(19) United States
(12) Patent Application Publication
(10) Pub. No.: US 2025/0380398 A1
(43) Pub. Date: Dec. 11, 2025

(54) STRUCTURES AND METHODS FOR FORMING 4F2 DYNAMIC RANDOM-ACCESS DEVICES

(71) Applicant: Applied Materials, Inc., Santa Clara, CA (US)

(72) Inventors: Zhijun Chen, San Jose, CA (US); Fredrick Fishburn, Los Gatos, CA (US); Raghuveer S. Makala, Campbell, CA (US); Balasubramanian Pranatharthiharan, San Jose, CA (US)

(73) Assignee: Applied Materials, Inc., Santa Clara, CA (US)

(21) Appl. No.: 19/205,327

(22) Filed: May 12, 2025

Related U.S. Application Data
(60) Provisional application No. 63/656,293, filed on Jun. 5, 2024.

(51) Int. Cl. H10B 12/00

(52) U.S. Cl. CPC H10B 12/05

(57) ABSTRACT

Disclosed are DRAM devices and methods of forming DRAM devices. One non-limiting method may include recessing a plurality of vertical pillars of a dynamic random-access memory cell within each contact opening of a plurality of contact openings, and forming a selective epitaxial material over the plurality of vertical pillars while the dynamic random-access memory cell is maintained at a temperature below 500° C.

### CROSS-REFERENCE TO RELATED APPLICATIONS

The present application claims priority to U.S. Provisional Patent Application No. 63/656,293, filed Jun. 5, 2024, and entitled “STRUCTURES AND METHODS FOR FORMING 4F2 DYNAMIC RANDOM-ACCESS DEVICE,” and incorporates its disclosure herein by reference in its entirety.

### FIELD

The present embodiments relate to semiconductor devices, and more particularly, to 4F2 dynamic random-access devices and approaches for forming.

### BACKGROUND

As dynamic random-access memory (DRAM) devices scale to smaller dimensions, an increasing emphasis is placed on patterning for forming three-dimensional structures, including trenches for storage nodes as well as access transistors. In current DRAM devices, transistors may be formed using narrow vertical semiconductor fin structures, often made from monocrystalline silicon. In accordance with current trends, the aspect ratio of such fin and trench structures may reach 30:1, which increases processing complexity.

In an effort to continue scaling smaller, 4F2 DRAM devices have been developed. 4F2 DRAM is an economical way to scale DRAM as three-dimensional (3D) DRAM becomes more feasible. Unlike current 6F2 DRAM where the cell transistor is U-shaped with both source and drain on the same side, the source and drain are at opposite sides of the vertical transistor in 4F2 DRAM. As a result, junctions for the source and drain are often done at different stages of processing. Because 4F2 DRAM typically requires at least one wafer bonding step, junction formation after the wafer bonding becomes challenging because of thermal budget constraints. That is, low temperature processes are needed without sacrificing dopant concentration or junction profile. It is with respect to these and other considerations, the present disclosure is provided.

### SUMMARY OF THE DISCLOSURE

The Summary is provided to introduce a selection of concepts in a simplified form, the concepts further described below in the Detailed Description. The Summary is not intended to identify key features or essential features of the claimed subject matter, nor is the Summary intended as an aid in determining the scope of the claimed subject matter.

In some approaches, a method may include recessing a plurality of vertical pillars of a dynamic random-access memory cell within each contact opening of a plurality of contact openings, and forming a selective epitaxial material over the plurality of vertical pillars while the dynamic random-access memory cell is maintained at a temperature below 500° C.

In some approaches, a method of forming a dynamic random-access memory cell may include providing a plurality of vertical pillars and a plurality of control gates, and forming a non-selective epitaxial material over the plurality of vertical pillars and the plurality of control gates while the dynamic random-access memory cell is maintained at a temperature below 500° C.

### BRIEF DESCRIPTION OF THE DRAWINGS

The accompanying drawings illustrate exemplary approaches of the disclosed embodiments so far devised for the practical application of the principles thereof.

FIG. 1A is a perspective view of a cell of a DRAM following formation of a plurality of contact openings, in accordance with embodiments of the present disclosure;

FIG. 1B is a perspective view of the cell of the DRAM following an ion implant, in accordance with embodiments of the present disclosure;

FIG. 1C is a perspective view of the cell of the DRAM following a channel recess process, in accordance with embodiments of the present disclosure;

FIG. 1D is a perspective view of the cell of the DRAM following formation of an epitaxial material and a thermal process, in accordance with embodiments of the present disclosure;

FIG. 1E is a perspective view of the cell of the DRAM following formation of an epitaxial material without a prior ion implant, in accordance with embodiments of the present disclosure;

FIG. 2 is a perspective view of a cell of a DRAM, in accordance with embodiments of the present disclosure;

FIG. 3A is a top view of the cell of the DRAM of FIG. 2, in accordance with embodiments of the present disclosure;

FIG. 3B is a top view of the cell of the DRAM following an ion implant, in accordance with embodiments of the present disclosure;

FIG. 3C is a top view of the cell of the DRAM following a blanket deposition of an epitaxial material, in accordance with embodiments of the present disclosure;

FIG. 3D is a top view of the cell of the DRAM following a selective etch to the epitaxial material, in accordance with embodiments of the present disclosure;

FIG. 3E is a top view of the cell of the DRAM following formation of a gapfill material and a thermal treatment, in accordance with embodiments of the present disclosure;

FIG. 4A is a top view of the cell of the DRAM of FIG. 2, in accordance with embodiments of the present disclosure;

FIG. 4B is a top view of the cell of the DRAM following a blanket deposition of an epitaxial material, in accordance with embodiments of the present disclosure;

FIG. 4C is a top view of the cell of the DRAM following a selective etch to the epitaxial material, in accordance with embodiments of the present disclosure;

FIG. 4D is a top view of the cell of the DRAM following formation of a gapfill material and an ion implant, in accordance with embodiments of the present disclosure;

FIG. 5 is a top view of a cell of a DRAM following a selective etch process to form a plurality of source/drains, in accordance with embodiments of the present disclosure;

FIG. 6 illustrates an example processing system, in accordance with embodiments of the present disclosure;

FIG. 7 is a flowchart of an approach for forming a cell of a device, in accordance with embodiments of the present disclosure;

FIG. 8 is a flowchart of an approach for forming a cell of a device, in accordance with embodiments of the present disclosure;

FIG. 9 is a flowchart of an approach for forming a cell of a device, in accordance with embodiments of the present disclosure; and

FIG. 10 is a flowchart of an approach for forming a cell of a device, in accordance with embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where embodiments of the methods are shown. The methods and devices may be embodied in many different forms and are not to be construed as being limited to the embodiments set forth herein. Instead, these embodiments are provided so the disclosure will be thorough and complete, and will fully convey the scope of the system and method to those skilled in the art.

The present embodiments provide novel devices and methods for forming such devices, such as transistors, formed from semiconductor fin structures. These approaches may be especially applicable to formation of DRAM devices, while other devices may also be formed according to the embodiments of the disclosure. Various non-limiting embodiments are particularly useful for enabling 4F2 DRAM junction formation with thermal budget constraints.

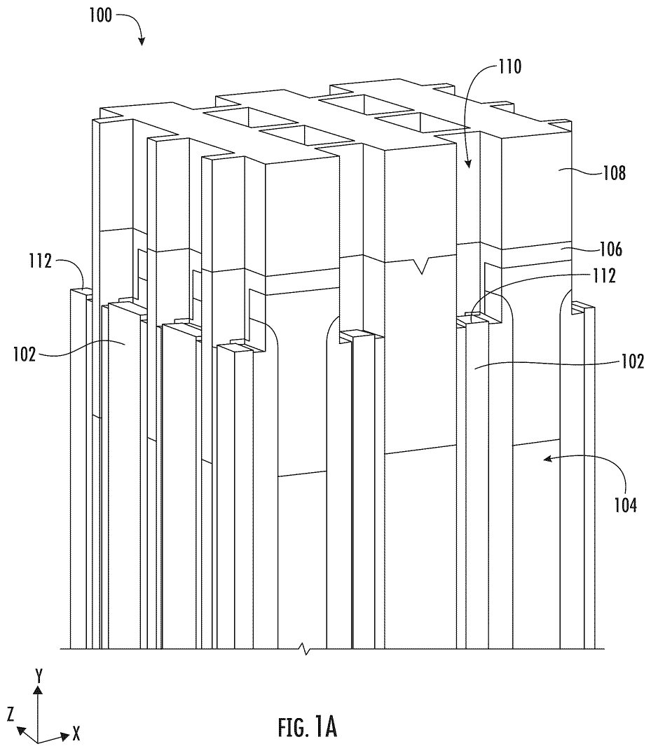

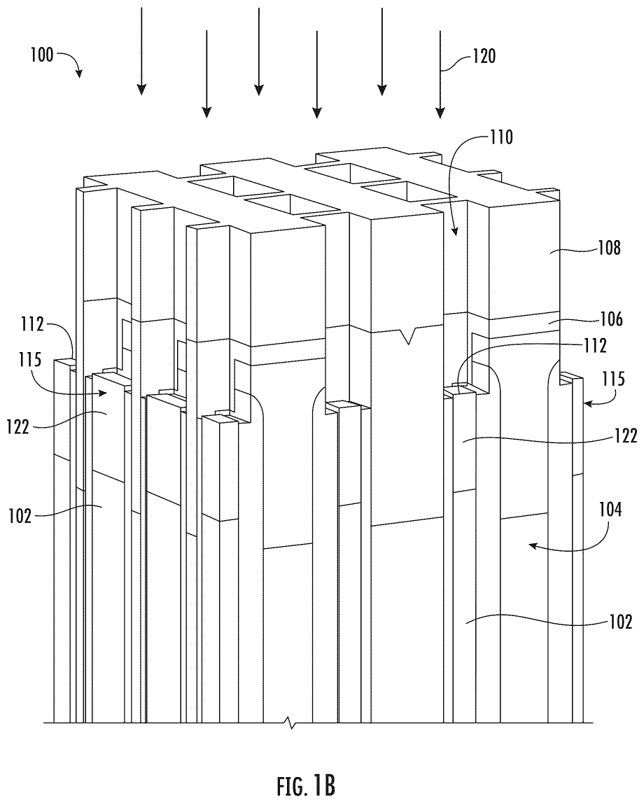

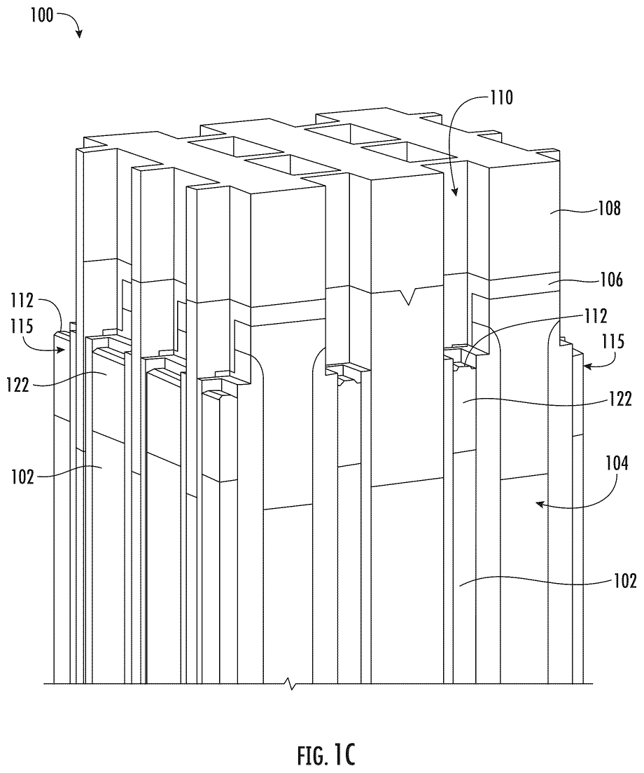

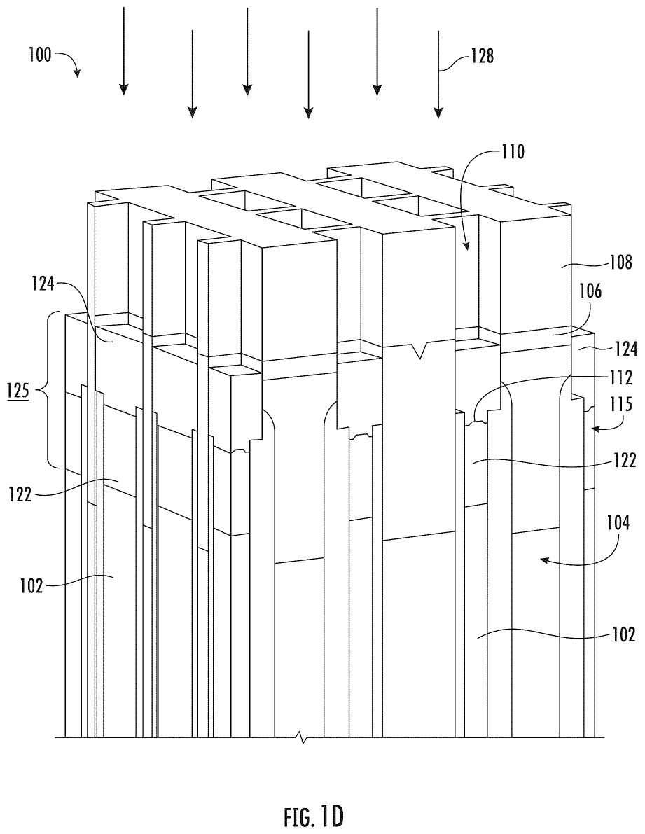

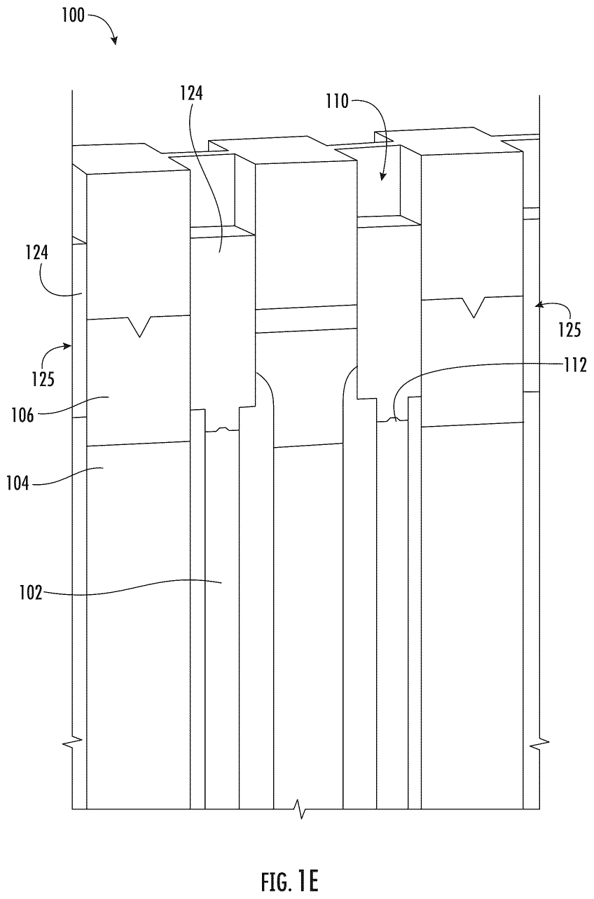

Turning now to FIG. 1A, a cell of a device 100, such as a DRAM device, will be described. The device 100 may include a plurality of vertical pillars 102 adjacent a plurality of control gates 104. In exemplary embodiments, the vertical pillars 102 may be an array of channel structures having a length or height extending primarily along a first direction (e.g., y-direction). According to various embodiments of the disclosure, the vertical pillars 102 may be monolithically formed with the same material (e.g., silicon) as a substrate (not shown). As will be appreciated, the device 100 may be used to make transistors and arrays of devices, such as DRAM arrays, having superior properties, including more uniformity in performance between devices, higher device yield, and so forth.

The device 100 may further include a liner layer 106 formed over the plurality of vertical pillars 102 and over the plurality of control gates 104. Although non-limiting, the liner layer 106 may be a dielectric (e.g., nitride or other similar material), which is conformally deposited over exposed areas of the device 100. An insulative layer 108 may then be formed over the liner layer 106, wherein the insulative layer 108 may be an oxide or other similar material.

As shown, the device 100 may include a plurality of contact openings 110 formed through the liner layer 106 and through the insulative layer 108. In some embodiments, liner layer 106 and the insulative layer 108 may be etched, for example, using a vertical reactive ion etch (RIE) process, to expose an upper surface 112 of vertical pillars 102 within each contact opening 110.

As shown in FIG. 1B, an optional ion implant 120 to the device 100 may be performed, whereby ions are directed through the contact openings 110 and into the upper surface 112 of an upper portion 115 of the vertical pillars 102 to form an implanted area, or a lightly doped drain (LDD) 122. In some embodiments, the ion implant 120 may be performed while a platen supporting the device 100 is held at a temperature greater than 300° C. or, in some cases, greater than 500° C. Although non-limiting, the ion implant 120 may include delivering ions into the upper portion 115 of the vertical pillars 102 at a desired concentration, dose, implant energy, etc., to form the LDD 122 of the channel. For example, in the case the ion implant 120 includes phosphorus ions, the phosphorous concentration (P %) may be approximately 1E20 to 1E17 atoms per cubic centimeter, implanted to a depth of approximately 5-40 nm (tunable), with minimal c-Si amorphization. Due to the nature of the ion implant 120, a gradient dopant concentration profile is normally present, wherein the minimum is for example 1E17 atoms per cubic centimeter and the max or peak concentration profile near the upper surface 112 may be approximately 1E19 to 5E20 atoms per cubic centimeter, as desired. In other embodiments, the ion implant 120 may include alternative ion species. For example, the ion implant 120 may alternatively include arsenic (As) or any n-type dopant.

The ion implant 120 may be a plasma-based doping (PLAD) or beamline implant. Although shown as a single implant, it will be appreciated that the ion implant 120 may include a series of multiple implants. In other embodiments, the ion implant 120 is not required at this stage of processing, e.g., in the case the LDD 122 has already been created upstream. In yet other embodiments, the LDD 122 is created using an epitaxial portion with gradient epitaxial growth, as will be described in greater detail below.

As shown in FIG. 1C, the upper portion 115 may optionally be recessed to remove damage to the upper surface 112 of the vertical pillars 102 caused by energetic ions from the contact etch and/or from the ion implant 120. In some embodiments, an etch may be performed through the contact openings 110.

As shown in FIG. 1D, an epitaxial material/layer 124 may be formed over the vertical pillars 102 to form a plurality of junctions 125. In some embodiments, the epitaxial material 124 may be formed within each of the contact openings 110 using a selective, low-temperature (e.g., below 500° C.) epi process to form the epitaxial material 124 atop each upper portion 115. Although non-limiting, the epitaxial material 124 can be a single/uniform active dopant concentration material, e.g., 5E20 atoms per cubic centimeter, or have a gradient active dopant concentration, e.g., from low (e.g., 1E17 atoms per cubic centimeter) to high (e.g., 5E10 atoms per cubic centimeter). In various embodiments, the epitaxial layer 124 may be formed to a thickness between 1 nm and 50 nm, wherein a 1 nm thickness may be appropriate for a high-dopant (e.g., P) capping layer, and a 50 nm thickness may be appropriate to form the entire junction 125 in the case where an implant or upstream LDD formation was not performed. For example, as shown in FIG. 1E, an approximately 5-50 nm layer of the n-doped epitaxial material 124, with a desired dopant concentration gradient, may be formed directly on the upper surface 112 of the vertical pillars 102, with proper preclean or damaged Si recess, as needed. The tunable peak active dopant concentraton may be approximately 1E20 to 1E21 atoms per cubic centimeter in various embodiments. Precursors for the epitaxial growth may include silane (SiH₄), disilane (Si₂H₆), trisilane (Si₃H₈), tetrasilane (Si₄H₁₀), dichlorosilane (H₂SiCl₂), trichlorosilane (HSiCl₃), germane (GeH₄), phosphine (PH₃), diborane (B₂H₆), arsine (AsH₃), methylsilane (H₃CSiH₃). The carrier gas may include N₂, H₂, Ar, He, or other inert or noble gases.

In the embodiment shown in FIG. 1D, the epitaxial material 124 is formed after the ion implant 120 is performed, wherein the junction 125 depth is defined by an implant depth plus the vertical thickness of the epitaxial material 124. However, in other embodiments, the epitaxial material 124 may be performed prior to the ion implant 120, or without any implant, as described above and demonstrated in FIG. 1E. This latter approach may be useful when minimal or no diffusion of dopant into the channel Si is desired. In this case, the dopant concentration and thickness of the epitaxial material 124 may be adjusted to meet device requirements of the junction 125. When no ion implant 120 is performed, the epitaxial material 124 constitutes the entire junction 125, and may have a gradient dopant profile from e.g., 1E17-1E18 atoms per cubic centimeter to e.g., 1E10-1E21 atoms per cubic centimeter. Furthermore, when the ion implant 120 is performed on top of the epitaxial material 124, some portion of the epitaxial material 124 may be undoped as deposited, and then doped to a desired level and depth with the ion implant 120.

An optional thermal treatment 128 may then be performed on the device 100, including on the epitaxial material 124. Although non-limiting, the thermal treatment 128 may be a dynamic surface anneal (DSA) operable to further drive-in and activate dopants of the junction 125. In some embodiments, the thermal treatment 128 results in a gradient dopant profile in the epitaxial material 124. Although not shown, processing of the device 100 may then continue, e.g., by depositing a material within the contact openings 110 to form a plurality of conductive features.

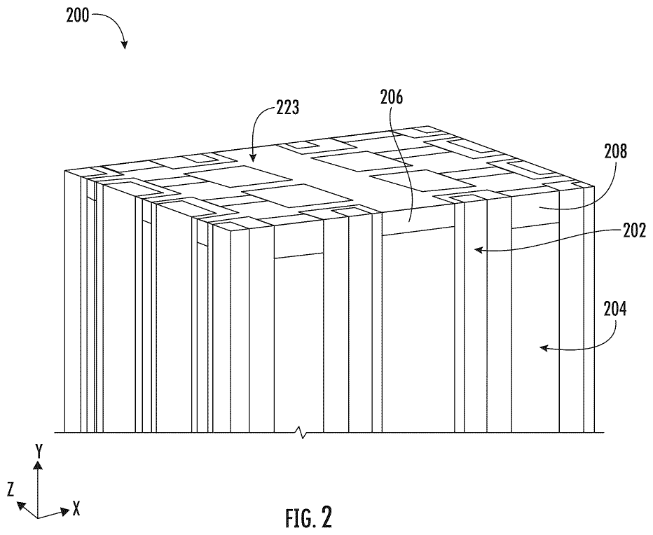

Referring to FIG. 2, another approach for forming junctions in a DRAM device 200 will be described. The device 200 may be the same or similar in many aspects to the device 100 described herein. As such, only certain aspects of the device 200 will hereinafter be described for the sake of brevity. The device 200 may include a plurality of vertical pillars 202 adjacent a plurality of control gates 204. Over the control gates 204 may be a liner layer 206 and an insulative layer 208. During processing, the liner layer 206 and the insulative layer 208 may be partially removed (e.g., planarized and recessed) to expose an upper surface 223 of the device 200. Unlike with device 100 described above, no contact openings are formed through the liner layer 206 and the insulative layer 208 to expose the vertical pillars 202.

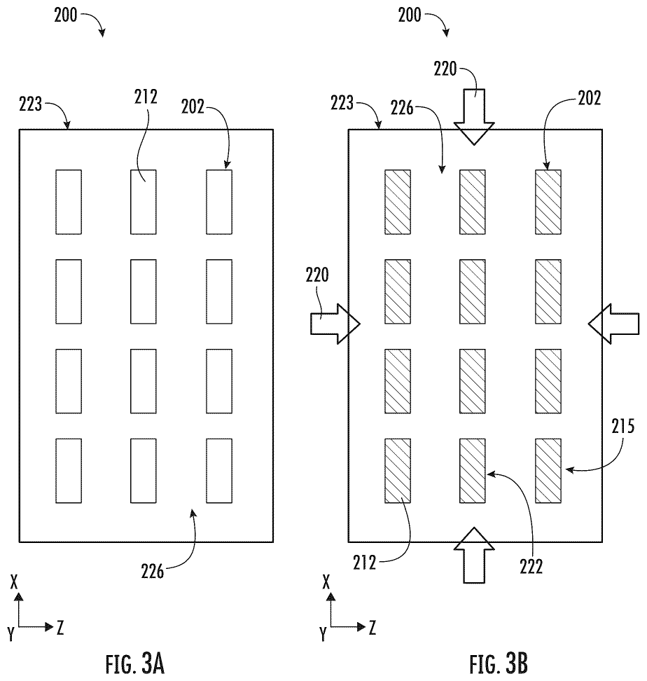

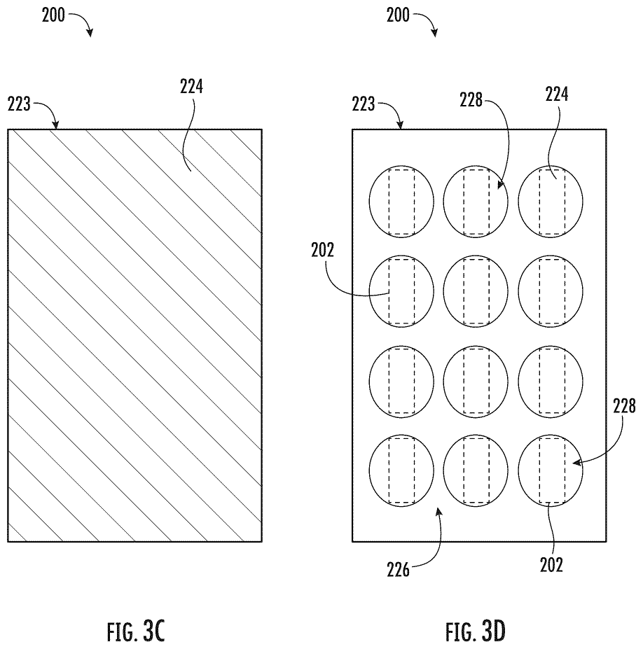

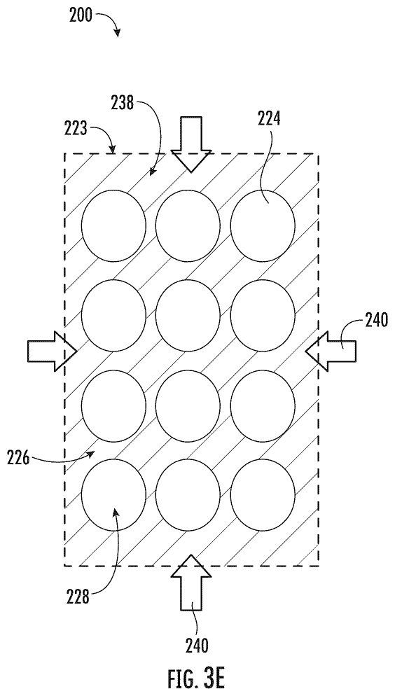

FIG. 3A is a simplified top view of the upper surface 223 of the device 200 following a planarization process using CMP, an RIE etch, or any other suitable removal process. As shown, the removal process may expose a top surface 212 of each of the vertical pillars 202, which may be arranged uniformly in a grid arrangement. Although not shown in detail, surrounding the upper surface 212 of the vertical pillars 202 may be one or more dielectric layers or areas 226 of the device 200.

As shown in FIG. 3B, an optional ion implant 220 to the device 200 may be performed, whereby ions are directed into the upper surface 223 of the device 200, including into the upper surface 212 of an upper portion 215 of the vertical pillars 202. In some embodiments, the ion implant 220 may be performed at a temperature greater than 300° C. and, in some cases, greater than 500° C. Although non-limiting, the ion implant 220 may include delivering ions into the upper portion 215 of the vertical pillars 202 at a desired concentration, dose, implant energy, etc., to form an implanted area, or LDD 222, of the channel. For example, in the case that the ion implant 220 includes phosphorous ions, the phosphorous concentration (P %) may be approximately 1E20 to 1E17 atoms per cubic centimeter, implanted to a depth of approximately 10-40 nm (tunable), with no c-Si amorphization. Due to the nature of the ion implant 220, a gradient dopant concentration profile is normally present, wherein the minimum is approximately 1E17 atoms per cubic centimeter (i.e., detection limit), and the max or peak concentration profile near the upper surface 212 may be approximately 1E19 to 5E20 atoms per cubic centimeter, as desired.

In other embodiments, the ion implant 220 may include alternative ion species, such as arsenic or any n-type dopant. Although shown as a single implant, it will be appreciated that the ion implant 220 may include a series of multiple implants. In other embodiments, the ion implant 220 is not required at this stage of processing, e.g., in the case the LDD 222 has already been created upstream, or in the case that the ion implant 120 is not required at all. In yet other embodiments, the LDD 222 is created using an epitaxial portion with gradient epitaxial growth.

In some embodiments, an optional selective etch back process may then be performed to recess the dielectric layer(s) 226 surrounding the vertical pillars 202. As a result, the upper portion 215 of the vertical pillars 202 will protrude above the dielectric layer 226, which aids with subsequent epitaxial formation.

In FIG. 3C, an epitaxial layer/material 224 may be formed over the upper surface 223 of the device 200 to form a plurality of junctions for the vertical pillars (not visible). In some embodiments, the epitaxial layer 224 may be a non-selective n-type epitaxial layer, for example an Si:P epitaxial layer, which is uniformly blanketed atop the upper surface of the vertical pillars 202 and the dielectric areas 226 (FIG. 3A). Precursors for the epitaxial growth may include silane (SiH₄), disilane (Si₂H₆), trisilane (Si₃H₈), tetrasilane (Si₄H₁₀), dichlorosilane (H₂SiCl₂), trichlorosilane (HSiCl₃), germane (GeH₄), phosphine (PH₃), diborane (B₂H₆), arsine (AsH₃), methylsilane (H₃CSiH₃). The carrier gas may include N₂, H₂, Ar, He, or other inert or noble gases. The epitaxial layer 224 can have a single/uniform active dopant concentration, e.g., at 1E20-1E21, or have a gradient active dopant concentration, e.g., from low (1E17-1E18 atoms per cubic centimeter) to high (1E10-1E21 atoms per cubic centimeter). In the case the epitaxial layer 224 has a gradient concentration, the ion implant 220 described above may or may not be needed.

The epitaxial material 224 may be formed after the ion implant 220 is performed, wherein the junction depth is defined by an implant depth plus the vertical thickness of the epitaxial material 224. In other embodiments, the epitaxial material 224 may be performed prior to the ion implant 220. In still other embodiments, the epitaxial material may be formed without any implant. This approach may be useful when minimal or no diffusion of dopant into channel Si is desired. For example, the epitaxial material 224, with a desired dopant concentration gradient, may be formed directly on the upper surface 212 of the vertical pillars 202, with proper preclean or damaged Si recess, as needed. In this case, the dopant concentration and thickness of the epitaxial material 224 may be adjusted to meet device requirements of the junction. When no ion implant 220 is performed, the epitaxial material 224 constitutes the entire junction, and may have a gradient dopant profile from e.g., 1E17-1E18 atoms per cubic centimeter to e.g., 1E10-1E21 atoms per cubic centimeter. In other embodiments, when the ion implant 220 is performed on top of the epitaxial material 124, some portion of the epitaxial material 124 may be undoped as deposited, and then doped to a desired level and depth with the ion implant 220.

In some embodiments, the epitaxial layer 224 may be formed using a low-temperature (e.g., below 500° C.) epi process. In various embodiments, the epitaxial layer 224 may be formed to a thickness between 1 mm and 50 nm.

As shown in FIG. 3D, the epitaxial layer 224 may be removed from over the dielectric areas 226. However, the epitaxial layer 224 may remain over the vertical pillars 202 to form a plurality of source/drains (S/D) 228 of the channel. Although non-limiting, a center of each S/D 228 is generally aligned with a center of each corresponding vertical pillar 202 beneath it. The shape and size of each S/D 228 may vary, as desired.

As shown in FIG. 3E, a gapfill 238 may then be formed over the upper surface 223 of the device 200. In some embodiments, the gapfill 238 may be a dielectric material which is deposited over the upper surface 223 and then planarized (e.g., CMP) or etched back (e.g., RIE) to expose the epitaxial layer 224 of the S/Ds 228. In other embodiments, the gapfill 238 may be formed only over the dielectric areas 226, between the S/D 228. The dielectric material of the gapfill 238 may be any of silicon oxide (SiO), silicon oxynitride (SiON), silicon oxycarbide (SiOC), silicon nitride (SiN), silicon oxynitride (SiOCN), silicon carbonitride (SiCN), etc. Although not shown, a conformal liner may optionally be formed over the upper surface 223 of the device 200 prior to the gapfill 238.

The device 200 may then receive an optional thermal treatment 240, which may be a DSA operable to further drive-in and activate dopants of the junction. In some embodiments, the thermal treatment 240 results in a gradient dopant profile in the S/Ds 228 of the junction. Although not shown, processing of the device 200 may then continue over the S/Ds 228 and over the gapfill 238.

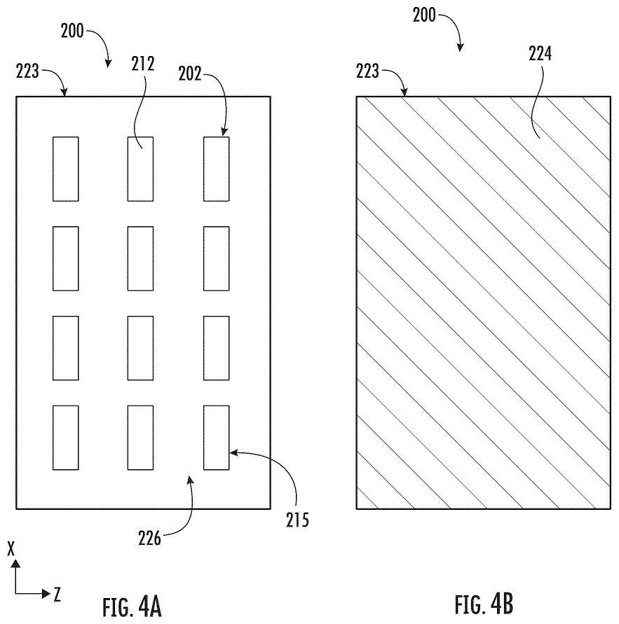

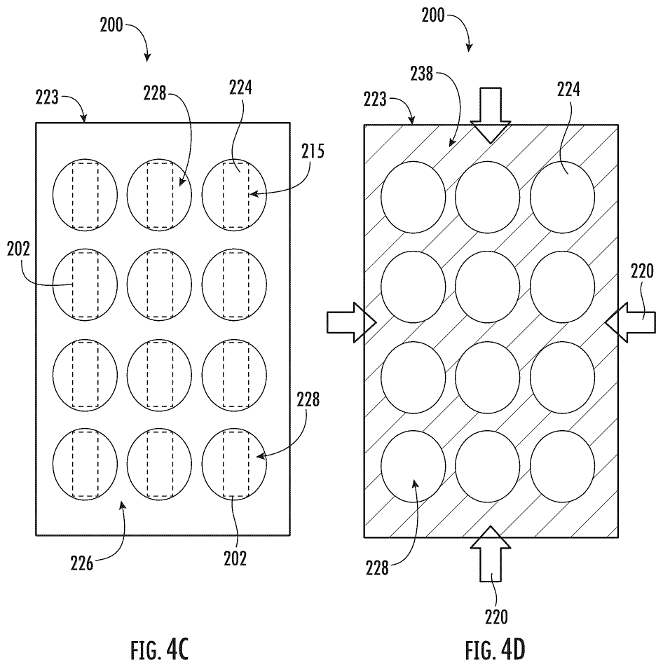

FIGS. 4A-4D demonstrate another approach for forming the DRAM device 200. FIG. 4A is a simplified top view of the upper surface 223 of the device 200 of FIG. 2 following a removal process to expose the top surface 212 of each upper portion 215 of the vertical pillars 202. Although not shown in detail, surrounding the upper surface 212 of the vertical pillars 202 may be one or more dielectric layers or areas 226.

In some embodiments, an optional selective etch back process may be performed to recess the dielectric layer(s) 226 surrounding the vertical pillars 202. As a result, the upper portion 215 of the vertical pillars 202 will protrude above the dielectric layer 226, which aids with subsequent epitaxial formation.

As shown in FIG. 4B, non-selective n-type epitaxial layer, for example Si:P epitaxial layer, 224 may be formed over the upper surface 223 of the device 200. The epitaxial layer 224 may uniformly blanket the upper portion 215 of the vertical pillars 202 and the dielectric areas 226. In various embodiments, the epitaxial layer 224 can be single concentration, i.e., when LDD 222 is formed upstream or downstream, e.g., using an ion implant, or it can be a gradient concentration to cover low to high, resulting in no upstream LDD formation or downstream implant being needed. In some embodiments, the epitaxial layer 224 may be formed using a low-temperature (e.g., below 500° C.) epi process.

As shown in FIG. 4C, the epitaxial layer 224 may be selectively removed from over the dielectric areas 226 but remain over the upper portion 215 of the vertical pillars 202 to form the plurality of source/drains (S/D) 228. Although non-limiting, a center of each S/D 228 is generally aligned with a center of each corresponding vertical pillar 202 beneath it. It will be appreciated that a shape and size of each S/D 228 may vary, as desired.

As shown in FIG. 4D, the gapfill 238 may then be formed over the upper surface 223 of the device 200. In some embodiments, the gapfill 238 may be a dielectric material which is deposited over the upper surface 223 and then planarized (e.g., CMP) or etched back (e.g., RIE) to expose the epitaxial layer 224 of the S/Ds 228. In various embodiments, the dielectric material of the gapfill 238 may be any of SiO, SiON, SiOC, SiN, SiOCN, SiCN, etc.

Ion implant 220 may optionally then be performed on the device 200, whereby ions are directed into the upper surface 223 of the device 200, including into the epitaxial layer 224 formed over the vertical pillars 202. In some embodiments, the ion implant 220 may be performed at a temperature greater than 300° C. and, in some cases, greater than 500° C. In other embodiments, the ion implant 220 may be performed at room temperature (e.g., 15-25° C.) or at a temperature less than room temperature.

When the ion implant 220 is performed on top of the epitaxial material 224, some portion of the epitaxial material 224 may be undoped as deposited, and then doped to a desired level and depth with the ion implant 220. For example, in one non-limiting embodiment, the active dopant concentration of the ion implant 220 may be approximately 1E20 to 1E17 atoms per cubic centimeter, implanted to a depth of approximately 10-40 nm (tunable), with no c-Si amorphization. Due to the nature of the ion implant 220, a gradient dopant concentration profile is normally present, wherein the minimum is approximately 1E17 atoms per cubic centimeter (i.e., detection limit), and the max or peak concentration profile near the upper surface 212 may be approximately 1E19 to 5E20 atoms per cubic centimeter, as desired. In other embodiments, the ion implant 220 may include alternative ion species, such as arsenic or any n-type dopant. The device 200 may then receive an optional thermal treatment, such as a DSA.

In still other embodiments, no ion implant 220 is performed on the epitaxial material 224, e.g., in the case and implant has already been performed upstream or will be subsequently performed downstream. This approach may be useful when minimal or no diffusion of dopant into the channel Si is desired. For example, the epitaxial material 224, with a desired dopant concentration gradient, may be formed directly on the upper surface 212 of the vertical pillars 202, with proper preclean or damaged Si recess, as needed. In this case, the dopant concentration and thickness of the epitaxial material 224 may be adjusted to meet device requirements of the junction. When no ion implant 220 is performed, the epitaxial material 224 constitutes the entire junction, and may have a gradient dopant profile from e.g., 1E17-1E18 atoms per cubic centimeter to e.g., 1E10-1E21 atoms per cubic centimeter.

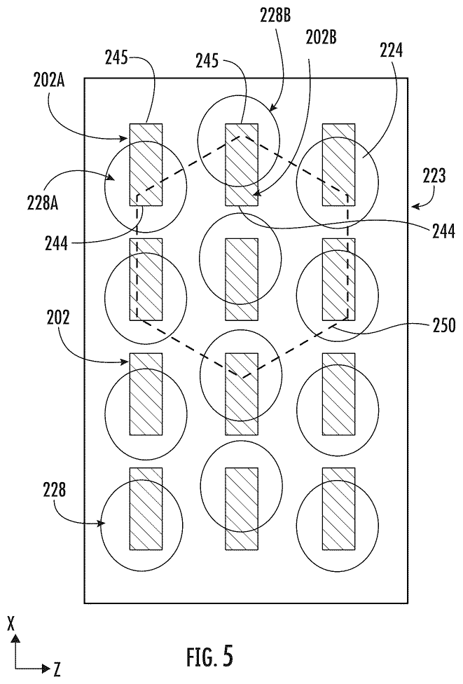

Device 200A of FIG. 5 demonstrates an alternative approach for forming the plurality of S/Ds 228 from the blanket epitaxial layer 224. As shown, the epitaxial layer 224 may be etched to remain only partially over the vertical pillars 202. Said differently, a center of each S/D 228 is generally shifted/offset relative to a center of each corresponding vertical pillar 202 beneath it to increase S/D density within the cell. For example, S/D 228A may be formed over a first end 244 of vertical pillar 202A, while second end 245 of vertical pillar 202A remains uncovered following the etch process to form S/D 228A. Meanwhile, S/D 228B is shifted along the x-direction such that S/D 228B is formed over the second end 245 of vertical pillar 202B but not over the first end 244. Although not limited to any particular shape or arrangement, the S/Ds 228 may be arranged into a hexagonal layout 250. The plurality of S/Ds 228 may be formed using any number of subtractive techniques.

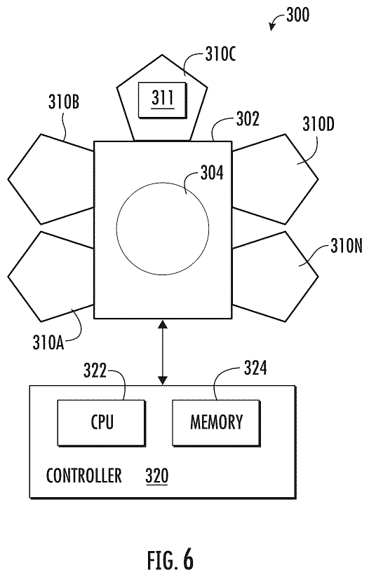

FIG. 6 shows a schematic of an example apparatus/system 300 according to embodiments of the disclosure. In some embodiments, the system 300 may be a cluster tool operable to perform processes necessary to form the devices described herein. Although non-limiting, the system 300 may include at least one central transfer station/chamber 302 and one or more robots 304 within the transfer station/chamber 302, wherein the robot 304 is operable to move a robot blade and a wafer to and from each of a plurality of processing chambers 310A-310N connected with, or positioned adjacent to, the transfer station/chamber 302. In some embodiments, the processing chambers 310A-310N may support angled beamline ion implantation, material deposition, and material etching. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 310A may be a deposition chamber, processing chamber 310B may be an etch chamber, and processing chamber 310C may house an ion processing tool 311 operable to perform the high-temperature implant process in which ions are directed into the stacks of layers, as described herein. In some embodiments, the ion processing tool 311 may be a thermion tool. In some embodiments, processing chamber 310D may be operable to perform one or more thermal processes, such as an anneal.

A system controller 320 is in communication with the robot 304, the transfer station/chamber 302, and the plurality of processing chambers 310A-310N. The system controller 320 can be any suitable component that can control the processing chambers 310A-310N and robot(s) 304, as well as the processes occurring within the process chambers 310A-310N. For example, the system controller 320 can be a computer including a central processing unit 322, memory 324, suitable circuits/logic/instructions, and storage.

Processes or instructions may generally be stored in the memory 324 of the system controller 320 as a software routine that, when executed by the processor 322, causes the processing chambers 310A-310N to perform processes of the present disclosure. For example, the memory 324 may store instructions executable by the processor 322 to direct ions into an upper portion of a plurality of vertical pillars using an implant performed at a temperature greater than 300° C., and to form an epitaxial material over the plurality of vertical pillars. The epitaxial material may be formed as a selective or non-selective layer over the plurality of vertical pillars and over the plurality of control gates.

The software routine may also be stored and/or executed by a second processor (not shown) that is remotely located from the hardware being controlled by the processor 322. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 322, transforms the general-purpose computer into a specific purpose computer (controller) that controls the chamber operation such that the processes are performed.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

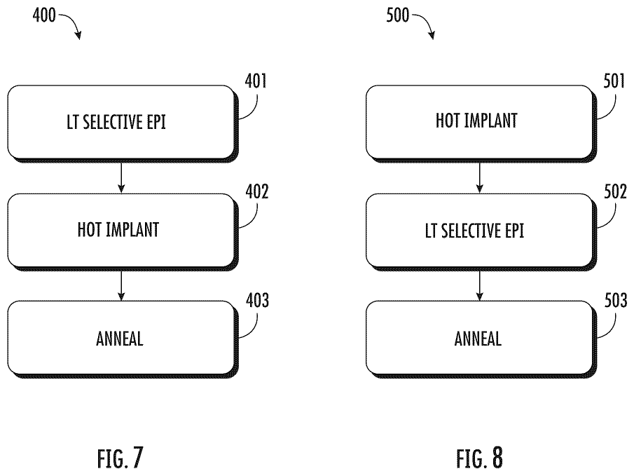

FIG. 7 is a flowchart of an approach 400 for forming a cell of a device, such as the device 100 described herein and shown in FIGS. 1A-1E. At block 401, the approach 400 may include forming a low-temperature selective epitaxial material over a plurality of vertical pillars of the device. In some embodiments, the selective epitaxial material may be formed while the device is maintained at a temperature below 500° C. In some embodiments, the selective epitaxial material is formed atop an upper portion of the vertical pillars, within contact openings which are formed through a liner layer and an insulative layer.

At block 402, the approach 400 may include a hot implant process. In some embodiments, ions are directed through contact openings and into the upper surface of the vertical pillars to form an implanted area. In some embodiments, the ion implant may be performed while a platen supporting the device is held at a temperature greater than 300° C. or, in some cases, greater than 500° C.

At block 403, the approach 400 may include performing an optional annealing process on the device. In some embodiments, the anneal may be a DSA operable to further drive-in and activate dopants of the junction. In some embodiments, the anneal may result in a gradient dopant profile in the selective epitaxial material.

FIG. 8 is a flowchart of an approach 500 for forming a cell of a device, such as the device 100 described herein and shown in FIGS. 1A-1E. At block 501, the approach 500 may include a hot implant process. In some embodiments, ions are directed through contact openings and into the upper surface of the vertical pillars to form the implanted area. In some embodiments, the ion implant may be performed while the platen supporting the device is held at a temperature greater than 300° C. or, in some cases, greater than 500° C.

At block 502, the approach 500 may include forming a low-temperature selective epitaxial material over the plurality of vertical pillars of the device. In some embodiments, the selective epitaxial material may be formed while the device is maintained at a temperature below 500° C.

At block 503, the approach 500 may include performing an optional annealing process. In some embodiments, the anneal may be a DSA operable to further drive-in and activate dopants of the junction. In some embodiments, the anneal may result in a gradient dopant profile in the selective epitaxial material.

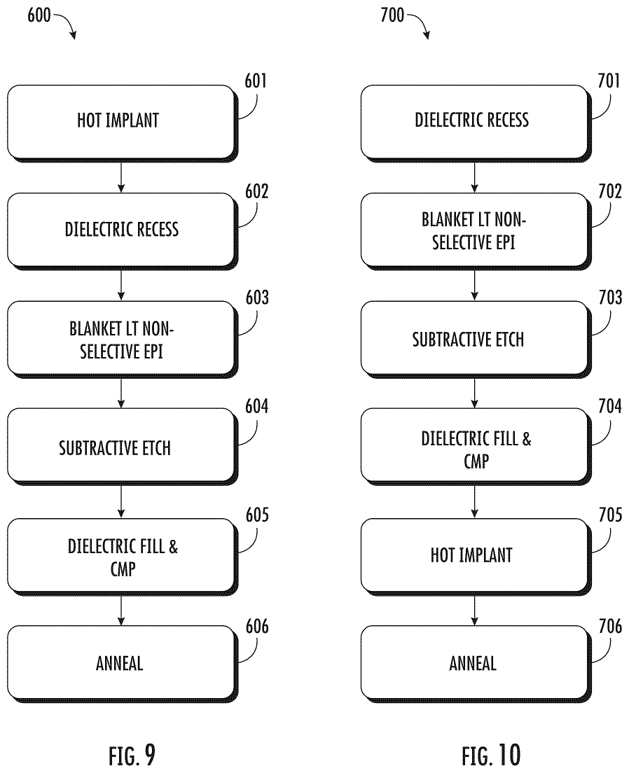

FIG. 9 is a flowchart of an approach 600 for forming a cell of a device, such as the device 200 described herein and shown in FIGS. 3A-3E. At block 601, the approach 600 may include performing an optional hot implant process. In some embodiments, ions are directed into an upper surface of a plurality of vertical pillars of the device. In some embodiments, the ion implant may be performed while the platen supporting the device is held at a temperature greater than 300° C. or, in some cases, greater than 500° C.

At block 602, the approach 600 may optionally include recessing a dielectric surrounding the plurality of vertical pillars. In some embodiments, a selective etch back process may be performed to recess the dielectric material selective to the vertical pillars. As a result, an upper portion of the vertical pillars will protrude above the dielectric to aid with subsequent epitaxial formation.

At block 603, the approach 600 may include forming a low-temperature, non-selective epitaxial material over the plurality of vertical pillars of the device. In some embodiments, the non-selective epitaxial material may be a blanket layer of epitaxial material, which is formed while the device is maintained at a temperature below 500° C.

At block 604, the approach 600 may include performing a subtractive Si:P etch to remove a first portion of the non-selective epitaxial material, wherein a second portion of the non-selective epitaxial material remains over the plurality of vertical pillars.

At block 605, the approach 600 may include depositing a dielectric fill over the device and performing a CMP. Following the CMP, the dielectric fill remains around the second portion of the non-selective epitaxial material.

At block 606, the approach 600 may include performing an optional anneal to the device.

FIG. 10 is a flowchart of an approach 700 for forming a cell of a device, such as the device 200 described herein and shown in FIGS. 4A-4D. At block 701, the approach 700 may optionally include recessing a dielectric surrounding a plurality of vertical pillars. In some embodiments, a selective etch back process may be performed to recess the dielectric material selective to the vertical pillars. As a result, an upper portion of the vertical pillars will protrude above the dielectric to aid with subsequent epitaxial formation.

At block 702, the approach 700 may include forming a low-temperature, non-selective epitaxial material over the plurality of vertical pillars of the device. In some embodiments, the non-selective epitaxial material may be formed while the device is maintained at a temperature below 500° C.

At block 703, the approach 700 may include performing a subtractive Si:P etch to remove a first portion of the non-selective epitaxial material, wherein a second portion of the non-selective epitaxial material remains over the plurality of vertical pillars.

At block 704, the approach 700 may include depositing a dielectric fill over the device and performing a CMP. Following the CMP, the dielectric fill remains around the second portion of the non-selective epitaxial material.

At block 705, the approach 700 may include performing an optional hot implant process. In some embodiments, ions are directed into the upper surface of the plurality of vertical pillars of the device while the platen supporting the device is held at a temperature greater than 300° C. or, in some cases, greater than 500° C.

At block 706, the approach 700 may include performing an optional anneal to the device.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

The use of “including,” “comprising,” or “having” and variations thereof herein is meant to encompass the items listed thereafter and equivalents thereof as well as additional items. Accordingly, the terms “including,” “comprising,” or “having” and variations thereof are open-ended expressions and can be used interchangeably herein.

The phrases “at least one”, “one or more”, and “and/or”, as used herein, are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the present disclosure, and do not create limitations, particularly as to the position, orientation, or use of this disclosure. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular approaches. Those skilled in the art will envision other modifications within the scope and spirit of the claims appended hereto.

What is claimed is:

1. A method, comprising:
recessing a plurality of vertical pillars of a dynamic random-access memory cell within each contact opening of a plurality of contact openings; and
forming a selective epitaxial material over the plurality of vertical pillars while the dynamic random-access memory cell is maintained at a temperature below 500° C.

2. The method of claim 1, further comprising directing ions into the plurality of vertical pillars using an implant performed at a temperature greater than 300° C.

3. The method of claim 2, wherein the selective epitaxial material is formed prior to directing the ions into the plurality of vertical pillars.

4. The method of claim 2, wherein the selective epitaxial material is formed after the ions are directed into the plurality of vertical pillars.

5. The method of claim 2, wherein directing ions into the plurality of vertical pillars further comprises delivering the ions through a plurality of contact openings formed through a liner layer and an insulative layer, wherein the liner layer and the insulative layer are formed over the plurality of vertical pillars, and wherein each contact opening of the plurality of contact openings extends to a corresponding vertical pillar of the plurality of vertical pillars.

6. The method of claim 5, wherein forming the selective epitaxial material over the plurality of vertical pillars comprises forming the selective epitaxial material within the plurality of contact openings.

7. The method of claim 2, wherein the implant is performed at a temperature greater than 500° C.

8. The method of claim 1, further comprising performing a thermal treatment to the dynamic random-access memory cell after the selective epitaxial material is formed over the plurality of vertical pillars.

9. A method of forming a dynamic random-access memory cell, the method comprising:
providing a plurality of vertical pillars and a plurality of control gates; and
forming a non-selective epitaxial material over the plurality of vertical pillars and the plurality of control gates while the dynamic random-access memory cell is maintained at a temperature below 500° C.

10. The method of claim 9, further comprising directing ions into an upper portion of the plurality of vertical pillars using an implant performed at a temperature greater than 300° C.

11. The method of claim 10, wherein the ions are directed into the upper portion of the plurality of vertical pillars prior to formation of the non-selective epitaxial material.

12. The method of claim 10, wherein the ions are directed into the upper portion of the plurality of vertical pillars after formation of the non-selective epitaxial material.

13. The method of claim 10, wherein forming the non-selective epitaxial material comprises depositing a blanket layer of the epitaxial material over the plurality of vertical pillars and over the plurality of control gates.

14. The method of claim 10, wherein the implant is performed at a temperature greater than 500° C.

15. The method of claim 10, further comprising performing a thermal treatment to the dynamic random-access memory cell.

16. The method of claim 10, further comprising:
removing a first portion of the non-selective epitaxial material, wherein a second portion of the non-selective epitaxial material remains over the plurality of vertical pillars; and
forming a gapfill material around the second portion of the non-selective epitaxial material.

17. The method of claim 16, further comprising planarizing the gapfill material.

18. The method of claim 16, wherein the implant is performed following formation of the gapfill material around the second portion of the non-selective epitaxial material.

19. The method of claim 16, further comprising recessing a dielectric surrounding the plurality of vertical pillars prior to forming the non-selective epitaxial material.
